(19) United States
(12) Patent Application Publication
(10) Pub. No.: US 2024/0105676 A1
(43) Pub. Date: Mar. 28, 2024

(54) INTEGRATED ELECTRONIC STRUCTURE AND DATA COMMUNICATION BETWEEN COMPONENTS OF THE STRUCTURE

(71) Applicant: ZERO EC SA, Vaumarcus (CH)

(72) Inventor: Erez HALAHMI, Givat Yearim (IL)

(21) Appl. No.: 17/768,504

(22) PCT Filed: Oct. 13, 2020
(86) PCT No.: PCT/IL2020/051094

§ 371 Date: Apr. 13, 2022

Related U.S. Application Data
(60) Provisional application No. 62/914,713, filed on Oct. 14, 2019.

(51) Int. Cl. H01L 25/065; H01L 23/00; H01L 23/50

(52) U.S. Cl. CPC H01L 25/0655; H01L 23/50; H01L 24/10

(57) ABSTRACT

An electronic assembly is provided for communication between electronic chips. The electronic assembly include a mechanical support carrying at least one basic block, which includes at least two electronic chips. At least one of the electronic chips is configured as a data signaling chip with respect to at least one other electronic chips for data communication to said at least one other electronic chip, and said at least one other electronic chip is configured as a data receiving chip with respect to said data signaling chip. The data signaling and data receiving chips face one another by their surfaces, respectively, being arranged in a spaced-apart relationship and defining together at least one interface region. The data communication from the data signaling chip to the at least one data receiving chip is in the form of at least one flux of charge carriers in free space propagation via a gap between said spaced-apart surfaces of the chips in said interface region, to selectively operate the at least one data receiving chip dependent on an operative state of at least one of the electronic chips of the basic block.

### TECHNOLOGICAL FIELD AND BACKGROUND

The present invention is in the field of integrated electronic structures and relates to an electronic assembly for use in the integrated electronic structure enabling communication between various active components (in particular, integrated circuits) of the integrated electronic structure.

An integrated structure is typically a multilayer structure including various patterned layers defining multiple active components (electronic chips) including functional elements of transistors, amplifiers, oscillators, etc. The functional elements of the active components of the integrated structure typically communicate with one another via signal or data exchange, by means of optical and/or electric and/or electromagnetic signals.

For example, U.S. Pat. No. 9,762,233, assigned to the assignee of the present application discloses a technique for contactless control of a Field Effect Transistor by controlling the electric field in the gate region of a FET without resorting to electrical conduction. According to this technique, an evacuated vessel is used preloaded with charge carriers creating free charges and having walls on which the free charges can scatter at least partially elastically. One end of the evacuated vessel, facing the gate region of the FET and being spaced therefrom while located in its proximity, is operable as a chargeable element, and the other end has a transmitter to accelerate the free charges in the evacuated vessel towards the first end, thereby effecting a change of an electric field in the space causing separation of charges in the gate region by electric field induction and modification of the charge distribution in the channel of the transistor, thereby modifying a conduction state of the transistor in a contactless manner.

### GENERAL DESCRIPTION

There is a need in the art for a novel approach for data communication between electronic chips of an electronic assembly/integrated electronic structure.

According to the conventional approach, functional elements of the active components of an integrated structure communicate with one another via signal or data exchange, using electrical connectors. However, electric connectors directly connecting between various active components (e.g. connection buses between processors or processor subsystems) unavoidably involve relatively strong dynamic currents, e.g. for example because of their relatively high capacity.

The present invention provides a novel electronic assembly for data/signal communication between electronic chips within an integrated structure via free space propagation of charge carriers. The electronic assembly comprises a substrate carrying at least one basic block formed by at least two electronic chips. At least one of these electronic chips is configured as a signaling chip with respect to at least one other electronic chip for data communication to said at least one other electronic chip, which is configured as a receiving chip with respect to the signaling chip. The data/signal communication is implemented via free space propagation of charge carriers through a gap between the signaling and receiving chips.

According to a broad aspect of the present invention, there is provided an electronic assembly comprising a substrate carrying at least one basic block of communicating electronic chips on its surface, the basic block comprising at least two electronic chips, wherein at least one of said at least two electronic chips is configured as a data signaling chip with respect to at least one other of said at least two electronic chips for data communication to said at least one other of the at least two electronic chips, and said at least one other of the at least two electronic chips is configured as a data receiving chip with respect to said data signaling chip, wherein the data signaling and data receiving chips face one another by their facing surfaces, respectively, being arranged in a spaced-apart relationship and defining together at least one interface region, said data communication from the data signaling chip to the at least one data receiving chip being in the form of at least one flux of charge carriers in free space propagation via a gap between the spaced-apart facing surfaces within said interface region, to selectively operate said at least one data receiving chip dependent on an operative state of at least one of the signaling and receiving chip of the basic block.

It should be noted that the term “facing surface” at time used herein below relates to a surface of the chip by which it interfaces the gap between this chip and at least one another chip of the same basic block. Such a facing surface may or may not be a “face” of the chip; in this connection the chips may be arranged face to face, or face to back, or back to back using TSV or activated evacuated vessel.

The flux of the charge carriers may be data modulated in accordance with the data to be communicated to the at least one receiving chip in the at least one interface region. Different profiles (values or patterns) of a data modulated signal provide respectively different operative states of a least one of the signaling and receiving chips of the basic block.

The basic block comprises at least one charge carriers' source configured and operable as a charge emitter of said charge carriers, and at least one data receiving signal communication port configured and operable to receive the charge carriers' flux to operate the respective receiving chip.

In some embodiments, the basic block comprises a pair of the electronic chips facing each other by their facing surfaces spaced by the gap (i.e. the surfaces interfacing the gap between them) and defining at least one first-type interface region. The first-type interface region is configured such that one of the electronic chips of the pair is configured as the data signaling chip and the other electronic chip of the pair is configured as the data receiving chip for the data communication between the first and second electronic chips in said first-type interface region.

For example, the first-type interface region comprises the charge carriers source located on one of the electronic chips and connected to a signal controller, to be operated by data modulated power supply from said signal controller, to generate said charge carriers' flux to propagate via said gap towards a data receiving signal communication port on the other electronic chip at least partially aligned with said charge carriers' source.

The data receiving signal communication port of the first-type interface region may, for example, be normally pre-charged, such that the charge carriers' flux arrival thereto affects a discharging process, thereby causing a change in the operational state thereof.

In some embodiments, the basic block comprises an additional first-type interface region, such that the two first-type interface regions are independently operated. Each of the electronic chips of the pair thus operates as the data signaling chip within one of the two first-type interface regions and operates as the data receiving chip within the other of the two first-type interface regions.

The additional first-type interface region may comprise an additional charge carriers' source located on said other of the two electronic chips and connected to a signal controller, to be operated by data modulated power supply from said signal controller, to generate an additional flux of the charge carriers to propagate via said gap towards a data receiving signal communication port on said one electronic chip at least partially aligned with said additional charge carriers' source.

In some embodiments, the basic block comprises a pair of the electronic chips facing each other and spaced from one another by the gap and defining at least one second-type interface region. The second type interface region is configured such that both of the electronic chips of the pair are configured and operable for directing and receiving the charge carriers' fluxes towards each other, while one of the electronic chips of the pair operates as the data signaling chip and the other electronic chip of the pair operates as the data receiving chip for the data communication between the first and second electronic chips in said second-type interface region.

In such embodiments, the data receiving chip comprises the charge carriers' source connected to a power supply to generate the flux of the charge carriers to propagate via the gap in the second-type interface region towards the signaling chip, and comprises the data receiving signal communication port. As for the data signaling chip, it comprises a signal receiver/responder at least partially aligned with said charge carriers' source and said data receiving signal communication port on the receiving chip and being connected to a signal controller, to be operated by data modulated power supply from said signal controller, to selectively absorb or deflect (by two different deflection regions) the charged carriers arrived from the charge carriers' source via said gap or redirect them to the data receiving signal communication port via said gap.

As described above, the data receiving signal communication port may be configured as a normally pre-charged electrode, such that the charge carriers' flux arrival thereto affects its discharge, thereby causing a change in the operational state thereof.

In some embodiments, the basic block comprises both the first-type interface region and the second-type interface region, which are independently operated.

In some embodiments, the basic block includes at least three electronic chips, wherein one of said at least three electronic chips faces the at least two other electronic chips via the gap, defining, respectively, at least two interface regions. Said one electronic chip is configured and operable as an electronic connector chip to communicate data from at least one of said at least two other electronic chips to the other of said at least two electronic chips via at least one charge carriers' guide located in the electron connector chip and extending between its first and second ends aligned with, respectively, the two interface regions.

In such embodiments, the first interface region may be associated with said one of said at least two other electronic chips. The first interface region comprises a charge carriers' source located on said electronic connector chip in proximity with the first end of the charge carriers' guide and connected to a power supply, and a receiver/responder located on said one of said at least two other electronic chips and being at least partially aligned with said charge carriers' source and said first end of the charge carriers' guide. The receiver/responder is connected to a signal controller, to be operated by data modulated power supply from said signal controller, to selectively absorb or, generally deflect, the charged carriers arrived from the charge carriers' source via said gap or redirect them to enter the charge carriers' guide via the first end thereof to propagate through the guide to the second end thereof at the second interface region, to direct the charge carriers' flux through the gap in the second interface region towards a data receiving signal communication port on said other of the two electronic chip.

The electronic connector chip may further comprise at least one additional charge carriers' guide extending between its first and second ends which are aligned with, respectively, the second and first interface regions. Such electronic connector chip is thereby configured and operable to communicate data from said other to said one of the two electronic chips.

The electronic connector chip may further comprise at least one floating charge carriers' source located at the second end of the at least one respective charge carriers' guide.

The charge carrier guide may be configured as an electrically conductive connector, e.g. a microchannel, which may be an evacuated vessel.

In the electronic assembly the two facing surfaces by which the two electronic chips face one another may be top and bottom surfaces of said electronic chips, respectively. The electronic chips are appropriately assembled on the surface of the common substrate, for example using support bumps, glue, wire bonding, etc.

In some embodiments, the surface of the substrate carrying the basic block(s) is substantially planar. In this case, the support bumps supporting the electronic chip(s) having the top facing surface are shorter than the support bumps supporting the electronic chip(s) having the bottom facing surface, to thereby define the gap between the facing surfaces.

In some other embodiments, the top surface of the substrate carrying the basic block(s) has a pattern defining a number of grooves corresponding to a number of basic blocks. In this case, each groove carries the electronic chip having the top facing surface and is surrounded by projection portions of the patterned substrate's surface carrying the electronic chips having bottom facing surfaces. In this configuration, the depth of the groove is selected to define the required gap between the facing surfaces.

### BRIEF DESCRIPTION OF THE DRAWINGS

In order to better understand the subject matter that is disclosed herein and to exemplify how it may be carried out in practice, embodiments will now be described, by way of non-limiting examples only, with reference to the accompanying drawings, in which:

FIGS. 1A and 1B schematically illustrate two examples, respectively, of a basic block of an electronic assembly according to some embodiments of the invention, according to which each electronic chip of the basic block is configured as either a data signaling chip or a data receiving chip, and the basic block has a single interface region;

FIGS. 2A and 2B illustrate schematically two examples, respectively, of a basic block configuration according to some other embodiments of the invention, where each of the electronic chips of the basic block 12 is operated as both the signaling chip and receiving chip;

FIGS. 3A to 3E exemplify yet another embodiment of the present invention, where FIG. 3A schematically illustrates the configuration of a basic block of the electronic assembly in which two electronic chips are associated with and communicate between them via an electronic connector chip; and FIGS. 3B to 3E schematically illustrate various operational stages of the basic block of FIG. 3A;

FIGS. 4A and 4B show two examples, respectively, of assembling the basic block(s) of the invention on a substrate having a substantially planar surface (FIG. 4A) and a patterned surface (FIG. 4B); and

FIG. 5 exemplifies an integrated structure configured according to the principles of the present invention including an array of basic blocks arranged in a spaced-apart fashion on the common substrate.

### DETAILED DESCRIPTION OF EMBODIMENTS

The present invention provides a novel electronic assembly configured for data/signal communication between electronic chips within an integrated structure. The electronic assembly comprises a substrate carrying at least two electronic chips, wherein at least one of them is configured as a signaling chip with respect to at least one other of the two or more electronic chips for data communication to said at least one other electronic chip, which is configured as a receiving chip with respect to the signaling chip. In some embodiments, the electronic chip is configured as the signaling chip with respect to at least one other receiving electronic chip and is configured as the receiving chip with respect to at least one other signaling chip.

The data/signal communication is implemented via free space propagation of charge carriers through a gap between the chips of the basic block. The gap may be evacuated or may be a gas filled space, as the case may be. The size of the gap is appropriately selected depending on the media therein.

It should be understood that, for a given media, the size of the gap is appropriately selected to provide effective passage of a flux of charge carriers being used.

More specifically, the invention deals with an electron flux, and is therefore described below with respect to this specific but not limiting example.

It should be noted that the spaced-apart communicating electronic chips may be assembled using separating elements, e.g. ring-like elements, as will be described below. Generally, any known suitable packaging technique can be used for this purpose.

More specifically, each of the signaling and receiving chips has a facing surface by which it faces the other of them. The transmission and/or reception action(s) is/are performed depending on operative state(s) of either one or both of the signaling and receiving chips, as will be described and exemplified specifically further below.

The electronic assembly of the invention may include one or more basic blocks sharing a common substrate or any other mechanical support, e.g. that can be made of several substrate elements. The basic block is a structure of communicating electronic chips, and such blocks may be arranged in an array. The basic blocks of the array may be independent blocks, or two locally adjacent basic clocks may have a common/shared signaling and/or receiving chip. This will also be described and exemplified specifically further below.

The electronic chips are typically mounted/assembled on the substrate by means of support bumps, which are configured to provide the desired gap between the communicating chips. As will be exemplified further below, the substrate's surface carrying the electronic chip may be planar or patterned.

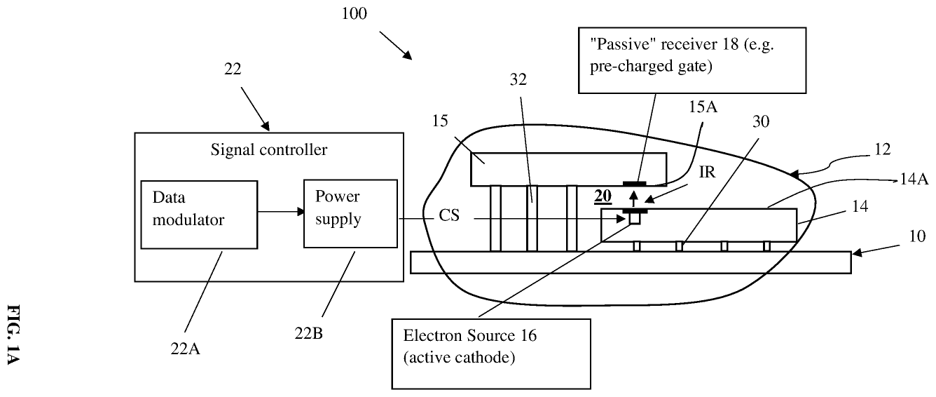

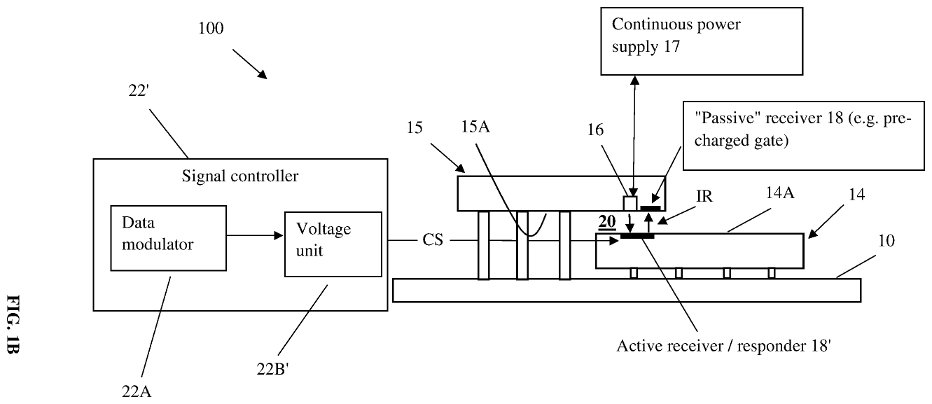

Referring to FIGS. 1A and 1B, there are schematically illustrated two examples, respectively, of the configurations of the basic block, generally at 100, according to some embodiments of the invention, according to which each electronic chip is configured as either a data signaling chip SC or a data receiving chip RC, and the basic block has a single interface region IR.

It should be noted that, in order to facilitate illustration and understanding, all the elements which are functionally similar in all the examples and embodiments described herein are identified by the same reference numbers.

FIG. 1A illustrates the electronic assembly 100 including a substrate 10 carrying at least one basic block 12—single such basic block being shown in the figure. The basic block includes at least one signaling chip 14 and at least one receiving chip 15—one pair of such chips being shown in the figure.

The signaling chip 14 and the receiving chip 15 have facing surfaces 14A and 15A by which they face one another and which are spaced-apart by a gap 20 for free space electron flux propagation. The facing surfaces present interfaces for communication between the chips.

The signaling chip 14 includes an electron source 16 (constituting a charge carriers' source), which may be constituted by a cathode configured as an electron emitter in a field emission configuration. In this example, the electron source 16 is a so-called “active source” in the meaning that it is connected to and operated by a power supply 22B, which in turn operates by a data pattern provided by a data modulator 22A. Thus, in this example, the signaling unit 14 is connected to a signal controller 22, which includes inter alia the data modulator 22A and the power supply 22B. In this example, the signal controller operates 22 as a transmitter controller.

The receiving chip 15 includes a data receiving signal communication port 18 (being a passive receiver in this example) which may be constituted by a chargeable electrode (anode). The electron source 16 (i.e. its interface part/aperture) on the signaling chip 14 is at least partially aligned with the passive receiver 18 on the receiving chip 15 defining together the interface region IR.

It should be understood, and this is common for all embodiments/examples described herein, that the electron source 16 may be configured for any suitable type of field emission, e.g., electric, photo or thermo emission or any combination thereof. The construction and operation of such electron sources are known per se and therefore need not be specifically described, except to note that it produces the appropriate electron flux.

Thus, in case of an “active source”, a control signal CS generated by the transmitter controller 22 to the electron source 16, is a data modulated signal, which may or may not be a binary signal. Different values/patterns of the data modulated signal results in respectively different operative states of the electron source, which operates accordingly for electron flux generation.

In the simplest example of “1” and “0” binary values of the control signal, the electron flux is, respectively, generated or not. It should, however, be understood that the invention is not limited to digital or analogue type of the control signal, as well as not limited to binary type digital control signal.

The basic block 12 operates as follows: The transmitter controller 22 operates to selectively provide the control signal CS to the active electron source 16, and a corresponding data modulated electron flux is generated, being shown in the figure by an arrow directed from the source 16 towards the receiving signal communication port 18. Thus, the receiving chip is operated by the electron flux from the signaling chip.

In a specific not limiting example of the anode-type passive data receiver 18, the anode may be “normally” pre-charged, e.g. positively charged in case of electron-based configuration, such that the electron flux arrival to the anode starts a discharging thereof corresponding to a respective operational state, e.g. “1”.

In the example of FIG. 1B, a so-called “mirror” configuration is exemplified. Here, although both of the electronic chips 14 and 15 are capable of transmitting/directing and receiving electron fluxes towards each other, while still only one of them is the data signaling chip and the other is the data receiving chip with respect to the data to be communicated, i.e. one is the “data source” and the other is the data receiver. In this example, however, the data receiving chip 15 is that which includes an electron source 16′ generating the electron flux, while the data signaling chip has an active data receiver/responder 18′ in the meaning that this receiver is connected to a signal controller 22′, which in this example operates as a receiver controller.

It should be understood that a receiver element 18′ is referred to as “active” since it is directly operated by the signal controller 22′ and is responsive to an electron flux. This is functionally different from what is referred to as “passive” receiver 18, which, while not being directly controlled by the data signal, operates its respective electronic chip.

Further, in this example, the electron source 16 is a continuously operated source appropriately connected to a continuous power supply 17, and further includes a “passive” signal communication port 18 located proximate to the electron source 16.

Both the electron source 16 (i.e. its interface part/aperture) and the passive receiver 18 are at least partially aligned with the active receiver 18′ on the signaling chip 14 defining together the interface region IR.

The signal controller 22′ includes a data modulator 22A and a voltage unit 22B′, which generates a data modulated voltage signal to the active data receiver 18′. Accordingly, the active data receiver 18′ has different operative states, depending on the voltage supply from unit 22B′ and thus differently receives or responds to the continuously supplied electron flux from the electron source 16. In the simplest example of binary data modulation, the voltage supply 22B′ provides relatively positive and relatively negative voltages on the active data receiver 18′, causing, respectively, absorption of the electrons by the active receiver 18′ and generation of a back flux of electrons towards the passive receiver 18 on the receiving chip 15.

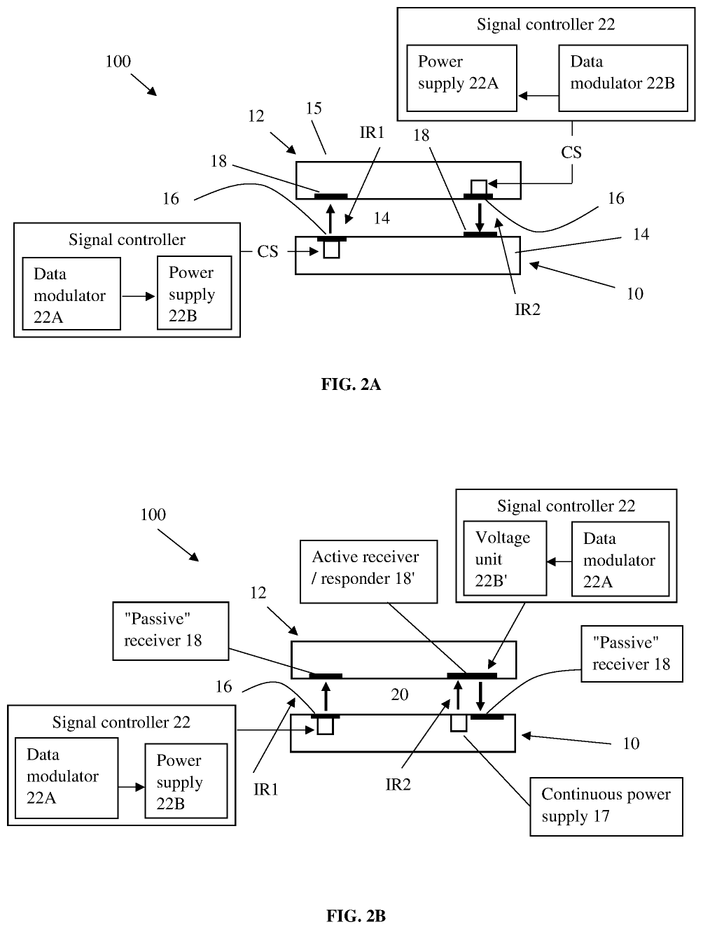

Reference is now made to FIGS. 2A and 2B, showing two examples, respectively, of some other embodiments of the invention, according to which each of the electronic chips 14 and 15 of the basic block 12 is operated as both the signaling chip SC and receiving chip RC. It should be understood, although not specifically shown in these figures, that the basic block 12 is located on top of any kind of a mechanical support, e.g. a substrate (10 in FIGS. 1A-1B) via respective support bumps (30 and 32 in FIGS. 1A-1B).

In both of these examples of FIGS. 2A and 2B, the basic block 12 has two communicating electronic chips 14 and 15 whose facing surfaces are spaced apart by a gap 20 and define two independently operated interface regions IR₁ and IR₂. It should be noted that data communications between the electronic chips 14 and 15 via the interface regions IR₁ and IR₂ can be implemented concurrently or in different time sessions, as the case may be.

In the example of FIG. 2A, each of the interface regions IR₁ and IR₂ is configured and operable similar to that of interface region IR in the above-described example of FIG. 1A. This is clearly shown in the figure in the self-explanatory manner and may thus be not specifically described again.

In the example of FIG. 2B, the interface regions IR₁ and IR₂ are configured and operable similar to the regions of the above-described examples of FIGS. 1A and 1B, respectively. This is clearly shown in the figure in the self-explanatory manner and may thus be not specifically described again.

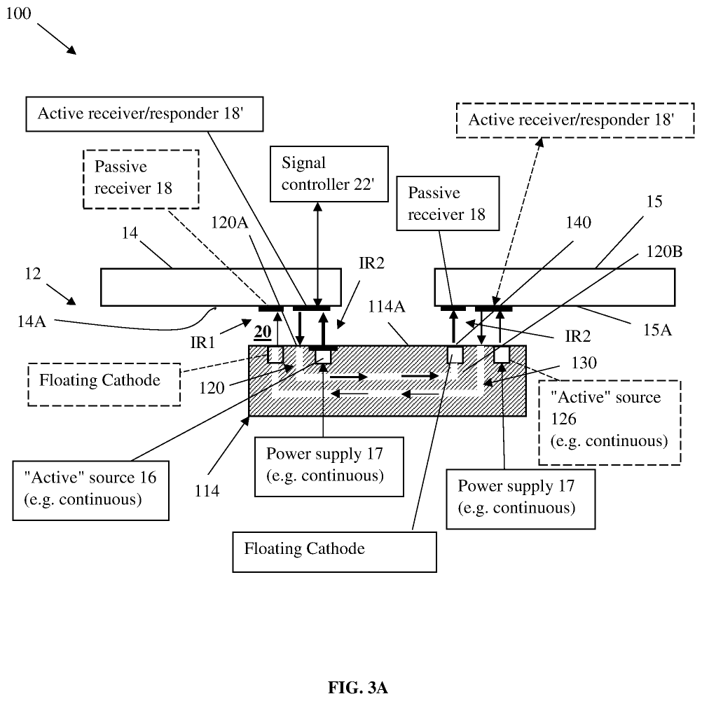

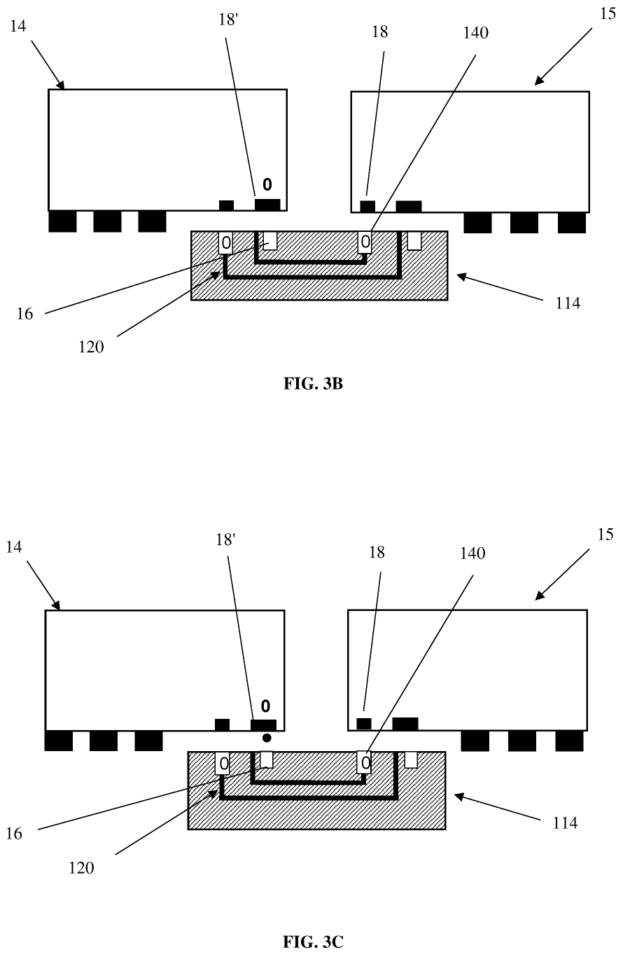

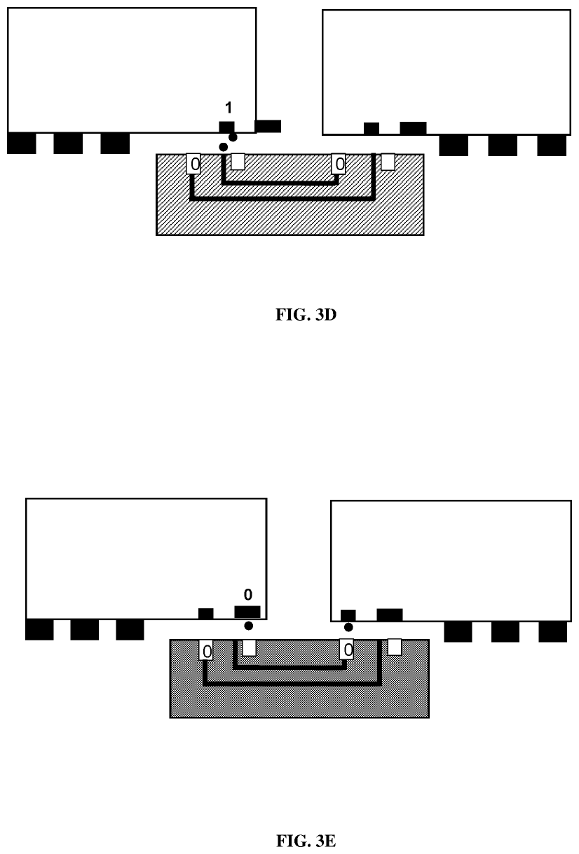

Reference is now made to FIGS. 3A to 3E exemplifying yet another embodiment of the present invention. FIG. 3A schematically illustrates the configuration of a basic block 12 of an electronic assembly 100 of the present invention; and FIGS. 3B to 3E schematically illustrate various operational stages of the electronic assembly 100. In this embodiment, the basic block 12 includes two electronic chips 14 and 15 which are associated with and communicate between them via an electronic connector chip 114. The electronic connector chip 114 is configured to provide data communication at least from one of the electronic chips 14 and 15 to the other, or from each one of them to the other.

It should be noted, although not specifically shown in these figures, that the elements of the electronic assembly are assembled/mounted via a mechanical support structure, e.g. on a common substrate (10 in FIGS. 1A and 1B), via support bumps (30 and 32 in FIGS. 1A and 1B).

The electronic connector chip 114 has a facing surface 114A by which (or by portions of which) it faces the surfaces (or portions thereof) of the electronic chips 14 and 15, so as to define two interface regions IR₁ and IR₂. The facing surfaces are spaced by a gap 20.

In the simplest example the electronic connector chip 114 is configured to communicate data from the electronic chip 14 to electronic chip 15. The electronic connector chip 114 includes two portions of the facing surface involved in two interface regions, respectively, which are connected between them by at least one charge carriers' guide, e.g. electrons' guide, 120.

Also, provided on the facing surface 114A are an electron source 16 connected to a power supply 17 (which in some embodiments is a continuous power supply). The electron source 16 and one end 120A of the electron guide 120 are located in proximity to one another and are at least partially aligned with an active receiver/responder 18′ (in the meaning as described above) directly connected and operated by data modulated control signal CS from a signal controller 22′. The opposite end 120B of the electron guide 120 is at least partially aligned with a passive receiver 18, which may be a pre-charged (e.g. positively pre-charged) anode.

As described above, the control signal operation provides that the active receiver/responder 18′ selectively deflects the electron flux from the source 16 or redirects it back towards the chip 114 (“mirror” configuration). However, in this embodiment, the redirected back flux enters the charge guide 120 at its end 120A and allows the electron flux propagation out of the guide via its opposite end 120B to free space propagation to the passive receiver 18. Thus, depending on the operative state of the active receiver/responder 18′ of the electronic chip 14, which operative state is controlled by the signal controller 22′, the passive receiver 18 of the electronic chip 15 differently interacts with the electron flux originated at the source 16 of the electronic connector chip 114. In the simplest example of binary control signal, the electronic chip 15 either receives data signal or not.

As shown in FIG. 3A, the electronic connector chip 114 preferably also includes a floating source (floating cathode) 140 at the opposite end 120B of the electron guide 120. The electron flux, while being redirected back from the responder 18′ into the electron guide's end 120A and reaching the floating cathode, causes successive electron emission from the floating cathode 140 thus creating a successive corresponding electron flux towards the passive receiver 18.

Thus, in this simplest example of this embodiment, the electronic chip 14 actually operates as the data signaling chip SC, and the electronic chip 15 operates as the data receiving chip RC.

As also shown in the figure using dashed lines, the electronic assembly 100 may be further configured for the similar data communication from the electronic chip 15 to electronic chip 14. To this end, the electronic connector chip 114 includes an additional electron guide 130 whose opposite ends are aligned (at least partially) with, respectively, an additional active receiver/responder 18′ on the electronic chip 15 (e.g. in the same interface region IR₂ or additional interface region, as the case may be), and an additional passive receiver 18 on the electronic chip 14 (e.g. in the same interface region IR₁ or additional interface region, as the case may be).

Also, the electron guide end 120B in the region IR₂ is located in proximity with an additional electron source 126 connected to a power supply 17 (additional or not, and which may or may not be a continuous power supply), and the opposite end of the additional electron guide in the region IR₁, either being associated with an additional floating source/cathode or not, is at least partially aligned with an additional passive receiver 18 on the electron chip 14.

It should be noted that the charge carriers guide may be configured as at least partially electrically conductive connector, for example configured as a microchannel, which may be an evacuated vessel. It should be understood that in the latter case, there is no need for any charged particles source like the floating cathode, since the charge carriers may be preloaded in the evacuated vessel.

FIGS. 3B to 3E exemplify the simplest-scenario operation of the electronic assembly 100 of FIG. 3A, i.e. for the binary digital data modulation.

Initially, as shown in FIG. 3B, the receiver/responder 18′ of the electron chip 14 is in the operational state corresponding to the binary data value “0”. As shown in FIG. 3C, the electron source 16 operates to provide the electron flux towards the receiver/responder 18′, which in said “0” state (e.g. relatively positive voltage) receives the electron flux. Then, as shown in FIG. 3D, the signal controller operates the receiver/responder 18′ to change its operational state to “1” (relatively negative voltage), and the electron flux is thus redirected back towards the electron chip connector where it enters the electron guide 120, through which the electron flux propagates towards the gap (e.g. via interaction with the floating cathode 140) and then interacts with the passive receiver 18 to thereby supply data to the electronic chip 15, as shown in FIG. 3E.

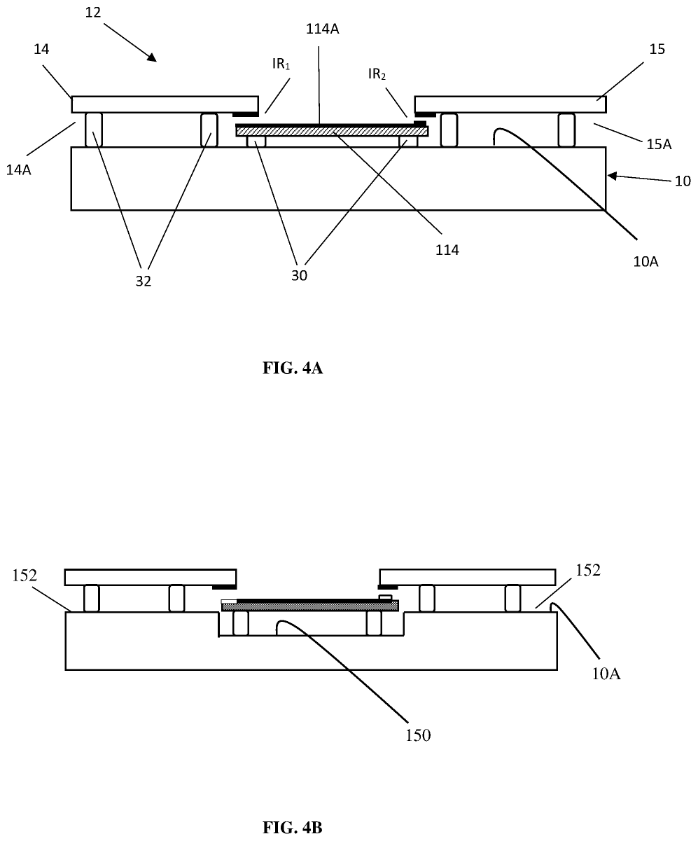

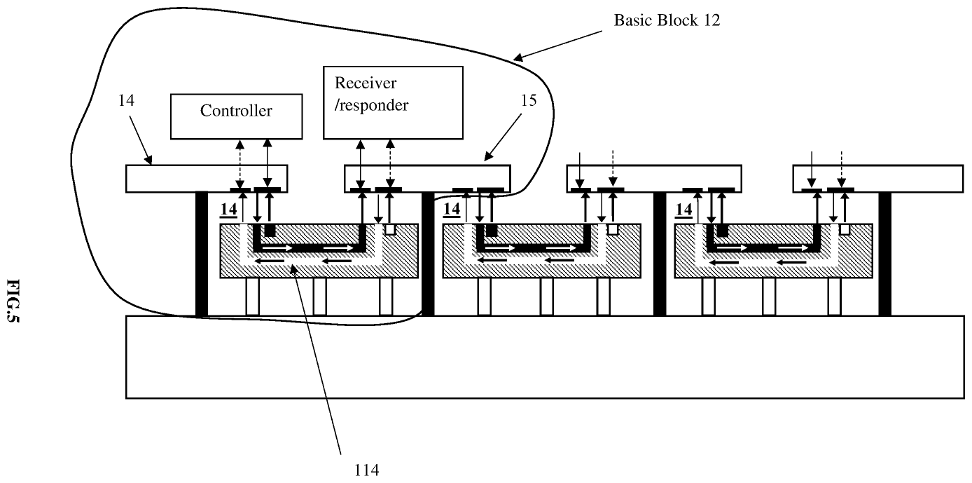

Referring now to FIGS. 4A and 4B, examples of assembling the basic block on a substrate are schematically illustrated.

In the example of FIG. 4A, the elements of the basic block are mounted on a planar surface 10A of the substrate 10. Accordingly, in order to provide the spaced-apart substantially parallel relationship between the top facing surface 114A of the electronic connector chip and bottom facing surfaces 14A and 15A of the electronic chips 14 and of the basic block 12, support bumps 32, on which the chips 14 and 15 are assembled, are longer/taller than support bumps 30 on which the connector chip 114 is assembled. The difference in the bumps' lengths is determined by the desired dimension of the gap between the facing surfaces, and possibly also a thickness of separating elements required for the packaging of the entire system. Chips 14 and 15 may touch chip 114 with a spacer between them.

In the example of FIG. 4B, the surface 10A of the substrate 10 on which the elements of the basic block 12 are mounted has a surface relief defining a groove 150 in between two substantially planar projections 152. The electronic connector chip 114 is assembled on its support bumps in the groove 150, while the electronic chips 14 and 15 are assembled on their support bumps on the planar projections 152 opposite sides of the groove 150.

With this configuration, peripheral regions of the top surface 114A of the connector chip 114 face and are aligned with peripheral regions of the bottom surfaces 14A and 15A of the electronic chips 14 and 15, respectively. In this case, the depth of the groove 150 may be determined by the required size of the gap (and possibly also those of the separating elements), and the bumps 30 and 32 may thus be of the same length. Chips 14 and 15 may touch chip 114 with a spacer between them.

As described above, the integrated structure may include an array of basic blocks arranged in a spaced-apart fashion on the common substrate. In this connection, reference is made to FIG. 5, exemplifying such a multi-block arrangement. It should be understood that although this specific example of FIG. 5 illustrates the basic block configuration generally similar to that of FIG. 3A, the same concept of multi-block arrangement may be applied to the basic block of any one of the above examples. Also, the example of FIG. 5 shows the use of substrate with the planar top surface. However, a patterned substrate surface can be used as well, e.g. as shown in FIG. 4B. In this case, the pattern would define a number of spaced-apart grooves corresponding to a number of basic blocks, such that each groove carries the electronic chip whose facing surface is the top one, and the adjacent projection(s) carries/carry the electronic connector chip(s) of the respective basic block whose facing surface(s) is/are the bottom one(s). It should be noted, although not specifically shown, that the array of multiple basic blocks may include similar basic blocks or different basic blocks, configured according to one or more of the above described embodiments.

1. An electronic assembly comprising a mechanical support carrying at least one basic block of communicating electronic chips on its surface, the basic block comprising at least two electronic chips, wherein at least one of said at least two electronic chips is configured as a data signaling chip with respect to at least one other of said at least two electronic chips for data communication to said at least one other of the at least two electronic chips, and said at least one other of the at least two electronic chips is configured as a data receiving chip with respect to said data signaling chip, wherein the data signaling and data receiving chips face one another by their surfaces, respectively, being arranged in a spaced-apart relationship and defining together at least one interface region, said data communication from the data signaling chip to the at least one data receiving chip being in the form of at least one flux of charge carriers in free space propagation via a gap between said spaced-apart surfaces of the chips in said interface region, to selectively operate said at least one data receiving chip dependent on an operative state of at least one of the electronic chips of the basic block.

2. The electronic assembly according to claim 1, wherein the flux of the charge carriers is data modulated in accordance with the data to be communicated to the at least one receiving chip in said at least one interface region.

3. The electronic assembly according to claim 2, wherein different profiles of a data modulated signal correspond to respectively different operative states of a least one of the electronic chips of the basic block.

4. The electronic assembly according to claim 1, wherein the basic block comprises at least one charge carriers' source configured and operable as a charge emitter of said charge carriers, and at least one receiving signal communication port configured and operable to receive the charge carriers' flux to operate the respective receiving chip.

5. The electronic assembly according to claim 4, wherein the basic block comprises a pair of the electronic chips facing each other by said surfaces spaced by said gap and defining at least one first-type interface region, the first-type interface region being configured such that one of the electronic chips of the pair is configured as the data signaling chip and the other electronic chip of the pair being is configured as the data receiving chip for the data communication between the first and second electronic chips in said first-type interface region.

6. The electronic assembly according to claim 5, wherein the first-type interface region comprises the charge carriers source located on one of the electronic chips and connected to a signal controller to be operated by data modulated power supply from said signal controller to generate said flux of the charge carriers to propagate via said gap towards a data receiving signal communication port on the other electronic chip at least partially aligned with said charge carriers' source.

7. The electronic assembly according to claim 6, wherein said data receiving signal communication port of said first-type interface region is normally pre-charged, such that the charge carriers' flux arrival to said data receiving signal communication port of said first-type interface region effects a discharging thereof thereby causing a change in the operational state thereof.

8. The electronic assembly according to claim 5, wherein the basic block comprises an additional first-type interface region, the two first-type interface regions being independently operated, such that each of the electronic chips of the pair operates as the data signaling chip within one of the two first-type interface regions and operates as the data receiving chip within the other of the two first-type interface regions.

9. The electronic assembly according to claim 8, wherein the additional first-type interface region comprises an additional charge carriers source located on said other of the electronic chips and connected to a signal controller to be operated by data modulated power supply from said signal controller to generate said flux of the charge carriers to propagate via said gap towards a data receiving signal communication port on said one electronic chip at least partially aligned with said additional charge carriers' source.

10. The electronic assembly according to claim 4, wherein the basic block comprises a pair of the electronic chips facing each other by said surfaces spaced by said gap and defining at least one second-type interface region, the second-type interface region being configured such that both of the electronic chips of the pair are configured and operable for directing and receiving the charge carriers' fluxes towards each other, while one of the electronic chips of the pair operating as the data signaling chip and the other electronic chip of the pair operating as the data receiving chip for the data communication between the first and second electronic chips in said second-type interface region.

11. The electronic assembly according to claim 10, wherein the data receiving chip comprises the charge carriers' source connected to a power supply to generate the flux of the charge carriers to propagate via the gap in said second-type interface region towards the signaling chip, and comprises the data receiving signal communication port; and the data signaling chip comprises a signal receiver/responder at least partially aligned with said charge carriers' source and said data receiving signal communication port on the receiving chip and being connected to a signal controller to be operated by data modulated power supply from said signal controller to selectively absorb the charged carriers arrived from the charge carriers' source via said gap or redirect them to the data receiving signal communication port via said gap.

12. The electronic assembly according to claim 11, wherein said data receiving signal communication port of said data receiving chip is normally pre-charged, such that the charge carriers' flux arrival to said data receiving signal communication port of said receiving chip effects a discharging thereof thereby causing a change in the operational state thereof.

13. The electronic assembly according to claim 5, wherein the basic block further comprises a second-type interface region, the first-type interface region and the second-type interface region being independently operated, the second type interface region being configured such that both of the electronic chips of the pair are configured and operable for directing and receiving the charge carriers' fluxes towards each other, while one of the electronic chips of the pair operating as the data signaling chip and the other electronic chip of the pair operating as the data receiving chip for the data communication between the first and second electronic chips in said second-type interface region.

14. The electronic assembly according to claim 13, wherein the data receiving chip comprises the charge carriers' source connected to a power supply to generate the flux of the charge carriers to propagate via the gap in said second-type interface region towards the signaling chip, and comprises the data receiving signal communication port; and the data signaling chip comprises a signal receiver/responder at least partially aligned with said charge carriers' source and said data receiving signal communication port on the receiving chip and being connected to a signal controller to be operated by data modulated power supply from said signal controller to selectively absorb the charged carriers arrived from the charge carriers' source via said gap or redirect them to the data receiving signal communication port via said gap.

15. The electronic assembly according to claim 14, wherein said data receiving signal communication port of said data receiving chip is normally pre-charged, such that the charge carriers' flux arrival to said data receiving signal communication port of said receiving chip effects a discharging thereof thereby causing a change in the operational state thereof.

16. The electronic assembly according to claim 1, wherein the basic block includes at least three electronic chips, wherein one of said at least three electronic chips faces the surfaces of the at least two other electronic chips via the gap between them defining, respectively, at least two interface regions, said one electronic chip being configured and operable as an electronic connector chip to communicate data from at least one of said at least two other electronic chips to the other of said at least two electronic chips via at least one charge carriers' guide, the charge carriers' guide being located in said electron connector chip and extending between its first end and a second ends aligned with, respectively, the two interface regions.

17. The electronic assembly according to claim 16, wherein the first interface region is associated with said one of said at least two other electronic chips and comprises a charge carriers' source located on said electronic connector chip in proximity with the first end of the charge carriers' guide and connected to a power supply, and a receiver/responder located on said one of said at least two other electronic chips and being at least partially aligned with said charge carriers' source and said first end of the charge carriers' guide, the receiver/responder being connected to a signal controller to be operated by data modulated power supply from said signal controller to selectively absorb the charged carriers arrived from the charge carriers' source via said gap or redirect them to enter the charge carriers' guide via the first end thereof to propagate through the guide to the second end thereof at the second interface region to direct the charge carriers' flux through the gap in the second interface region towards a data receiving signal communication port on said other of the two electronic chip.

18. The electronic assembly according to claim 16, wherein the electronic connector chip further comprises at least one additional charge carriers' guide extending between its first and second ends aligned with, respectively the second and first interface regions, said electronic connector chip being thereby configured and operable to communicate data from said other to said one of the two electronic chips.

19. The electronic assembly according to claim 18, wherein the second interface region comprises an additional charge carriers' source located on said electronic connector chip in proximity with the first end of the additional charge carriers' guide and connected to a power supply, and an additional receiver/responder located on said other of said at two electronic chips and being at least partially aligned with said additional charge carriers' source and said first end of the additional charge carriers' guide, the additional receiver/responder being connected to a signal controller to be operated by data modulated power supply from said signal controller to selectively absorb the charged carriers arrived from the additional charge carriers' source via the gap or redirect them to enter the additional charge carriers' guide via the first end thereof to propagate through the additional guide to the second end thereof at the first interface region to direct the charge carriers' flux through the gap in the first interface region towards an additional data receiving signal communication port on said one of the two electronic chips.

20. The electronic assembly according to claim 17, wherein the electronic connector chip further comprises at least one floating charge carriers' source located at the second end of the at least one respective charge carriers' guide.

21. The electronic assembly according to claim 17, wherein the charge carriers guide is configured as at least partially electrically conductive connector.

22. The electronic assembly according to claim 21, wherein the charge carriers guide is configured as a microchannel.

23. The electronic assembly according to claim 21, wherein the charge carriers guide is configured as an evacuated vessel.

24. The electronic assembly according to claim 1, wherein the two surfaces of the electronic chips by which said two electronic chip face one another are top and bottom surfaces of the two electronic chips, respectively.

25. The electronic assembly according to claim 1, wherein the electronic chips are assembled on said surface of the mechanical support via support bumps.

26. The electronic assembly according to claim 1, wherein said surface of the mechanical support carrying the at least one basic block is substantially planar,

27. The electronic assembly according to claim 24, wherein said surface of the mechanical support carrying the at least one basic block is substantially planar, the support bumps supporting the at least one electronic chip having the top facing surface are shorter than the support bumps supporting the at least one electronic chip having the bottom facing surface, to thereby define said gap between the facing surfaces.

28. The electronic assembly according to claim 24, wherein the top surface of the mechanical support has a pattern defining a number of grooves corresponding to a number of basic blocks, each groove carrying the electronic chip having the top surface by which it faces at least one bottom surface of, respectively, at least one electronic chip located on at least one adjacent projection portion of said surface of the mechanical support carrying the electronic chips.

29. An electronic assembly comprising a mechanical support carrying at least one basic block of communicating electronic chips on its surface, the basic block comprising at least a pair of electronic chips, wherein at least one electronic chip of the pair is configured as a data signaling chip with respect to the other electronic chip of the pair for data communication to said other electronic chip, and said other electronic chip is configured as a data receiving chip with respect to said data signaling chip, wherein: the data signaling and data receiving chips are arranged in spaced-apart planes, the data signaling chip comprises a charge carrier's source, and the data receiving chip comprises a signal receiving port, said charge carrier source and said signal receiving port face one another by their surfaces defining together an interface region, said data communication from the data signaling chip to the data receiving chip being in the form of at least one flux of said charge carriers in free space propagation via a gap between said facing surfaces of the charge carrier source and said signal receiving port in said interface region, to selectively operate said at least one data receiving chip dependent on an operative state of at least one of the electronic chips of the basic block.
